(19) United States
(12) Patent Application Publication
(10) Pub. No.: US 2026/0053022 A1
(43) Pub. Date: Feb. 19, 2026

(54) WIRING BOARD, ELECTRONIC MODULE, AND MANUFACTURING METHOD FOR WIRING BOARD

(71) Applicant: Murata Manufacturing Co., Ltd., Nagaokakyo-shi (JP)

(72) Inventors: Hideki UEDA, Nagaokakyo-shi (JP); Nobuo IKEMOTO, Nagaokakyo-shi (JP); Tomohiro FURUMURA, Nagaokakyo-shi (JP); Naoki MINAMIDANI, Nagaokakyo-shi (JP)

(73) Assignee: Murata Manufacturing Co., Ltd., Nagaokakyo-shi (JP)

(21) Appl. No.: 19/370,813

(22) Filed: Oct. 28, 2025

Related U.S. Application Data
(63) Continuation of application No. PCT/JP2024/004285, filed on Feb. 8, 2024.

(30) Foreign Application Priority Data
May 1, 2023 (JP) 2023-075390

(51) Int. Cl. H01L 23/498; H01L 21/48; H01L 23/00; H05K 1/11; H05K 3/10

(52) U.S. Cl. CPC H01L 23/49827; H01L 21/486; H01L 23/49866; H05K 1/113; H05K 3/107; H01L 24/16; H01L 2224/16227; H01L 2224/16237; H05K 2201/0141; H05K 2201/0154; H05K 2201/032; H05K 2201/0939; H05K 2201/09481; H05K 2201/09563; H05K 2203/072; H05K 2203/0723

(57) ABSTRACT

In a first insulating layer, a through-hole penetrates the first insulating layer in the thickness direction. A first conductor pattern is on a first surface that is one surface of the first insulating layer. The first conductor pattern closes the opening of the through-hole on the side of the first surface. A first connection conductor is in the through-hole. The first connection conductor is connected to the first conductor pattern, and the dimension of the first connection conductor in the thickness direction is smaller than the dimension of the first insulating layer in the thickness direction. A metal element with the maximum content in the first conductor pattern is the same as a metal element with the maximum content in the first connection conductor.

### CROSS-REFERENCE TO RELATED APPLICATIONS

The present application is a continuation of PCT Application No. PCT/JP2024/004285, filed Feb. 8, 2024, which claims priority to Japanese patent application 2023-075390, filed May 1, 2023, the entire contents of each of which being incorporated herein by reference.

### TECHNICAL FIELD

The present disclosure relates to a wiring board, an electronic module, and a manufacturing method for a wiring board.

### BACKGROUND ART

Various wiring boards on which electronic components are mounted are publicly known (Patent Documents 1, 2, and 3). Wiring boards disclosed in Patent Documents 1 and 2 include an inner layer conductor pattern on a substrate and a coating layer (insulator layer) that covers the inner layer conductor pattern. A cavity is made in the coating layer, and part of a surface of the inner layer conductor pattern is exposed at the bottom surface of the cavity. The surface exposed in the cavity in the inner layer conductor pattern is covered by a surface treatment portion (surface layer). The portion exposed in the cavity in the inner layer conductor pattern is used as a terminal for mounting an electronic component. The surface treatment portion functions as a connection conductor for connecting a solder bump or the like of the electronic component to the inner layer conductor pattern.

A copper foil is used for the inner layer conductor pattern disclosed in Patent Document 1, and solder, an alloy, gold, silver, nickel, or the like is used for the surface treatment portion. A metal composed mainly of copper is used for the inner layer conductor pattern disclosed in Patent Document 2, and Ni—Au plating or Sn (solder) plating is used for the surface layer. The surface layer protects the inner layer conductor pattern under the surface layer.

In the wiring board disclosed in Patent Document 3, a through-hole that penetrates a first resin layer is filled with a connection conductor. The connection conductor is connected to an inner layer conductor pattern as a lower layer. A second resin layer is disposed on the first resin layer, and a cavity that exposes the connection conductor is made in the second resin layer. The connection conductor exposed in the cavity is used as a terminal for mounting an electronic component. A bonding material of a melting point change type is used for the connection conductor.

### CITATION LIST

### Patent Documents

Patent Document 1: Japanese Unexamined Patent Application Publication No. 2005-235981
Patent Document 2: Japanese Unexamined Patent Application Publication No. 2005-244108
Patent Document 3: International Publication No. 2015/170539

### SUMMARY

### Technical Problems

A stress attributed to shape discontinuity is likely to concentrate at the interface between the conductor pattern of the inner layer and the connection conductor in the wiring boards disclosed in Patent Documents 1, 2, and 3. Further, the conductor pattern of the inner layer and the connection conductor are formed of different materials. Thus, a crack attributed to the stress concentration is likely to occur at the interface between the conductor pattern of the inner layer and the connection conductor. The present disclosure is directed to providing a wiring board in which a crack is less likely to occur at the interface between a conductor pattern and a connection conductor. The present disclosure is also directed to providing an electronic module using this wiring board. The present disclosure is further directed to providing a manufacturing method for this wiring board.

### Solutions to Problems

According to an aspect of the present disclosure, there is provided a wiring board including a first insulating layer in which a through-hole that penetrates the first insulating layer in a thickness direction is made, a first conductor pattern on a first surface and closes an opening of the through-hole on a side of the first surface, the first surface being one surface of the first insulating layer, and a first connection conductor in the through-hole and is connected to the first conductor pattern. A dimension of the first connection conductor in the thickness direction is smaller than a dimension of the first insulating layer in the thickness direction. A metal element with maximum content in the first conductor pattern is the same as a metal element with maximum content in the first connection conductor.

According to another aspect of the present disclosure, there is provided an electronic module including the wiring board, and an electronic component mounted on the wiring board, with a solder bump interposed therebetween, wherein the solder bump is connected to the first connection conductor.

According to further aspect of the present disclosure, there is provided a manufacturing method for a wiring board, the manufacturing method including preparing a first insulating layer having a first surface on which a first conductor pattern is formed, the first surface being one surface of the first insulating layer, forming a through-hole that reaches the first conductor pattern from a surface on the opposite side to the first surface in the first insulating layer, and forming a first connection conductor in the through-hole by a plating method with use of the first conductor pattern as a seed. A metal element with maximum content in the first conductor pattern is the same as a metal element with maximum content in the first connection conductor. A dimension of the first connection conductor in a thickness direction is smaller than a dimension of the first insulating layer on the first conductor pattern in the thickness direction.

### Advantageous Effects

The metal element with the maximum content in the conductor pattern is the same as the metal element with the maximum content in the connection conductor. Thus, discontinuity of the material at the interface between both components is alleviated. This can suppress the occurrence of a crack and delamination attributed to concentration of a stress at the interface between the conductor pattern and the connection conductor.

### BRIEF DESCRIPTION OF DRAWINGS

FIG. 1 is a sectional view of a wiring board according to a first example.

FIGS. 2A and 2B are sectional views of the wiring board according to the first example at a stage in the middle of manufacturing.

FIG. 3 is a sectional view of a wiring board according to a second example.

FIG. 4 is a sectional view of the wiring board for explaining an excellent effect of the second example.

FIG. 5 is a sectional view of an electronic module according to a third example.

FIG. 6 is a sectional view of a wiring board according to a fourth example.

FIG. 7 is a sectional view of a wiring board according to a modification of the fourth example.

FIG. 8 is a sectional view of a wiring board according to another modification of the fourth example.

FIG. 9 is a sectional view of a wiring board according to further modification of the fourth example.

FIG. 10 is a sectional view of a wiring board according to a fifth example.

FIG. 11 is a sectional view of a wiring board according to a modification of the fifth example.

### DESCRIPTION OF EMBODIMENTS

### First Example

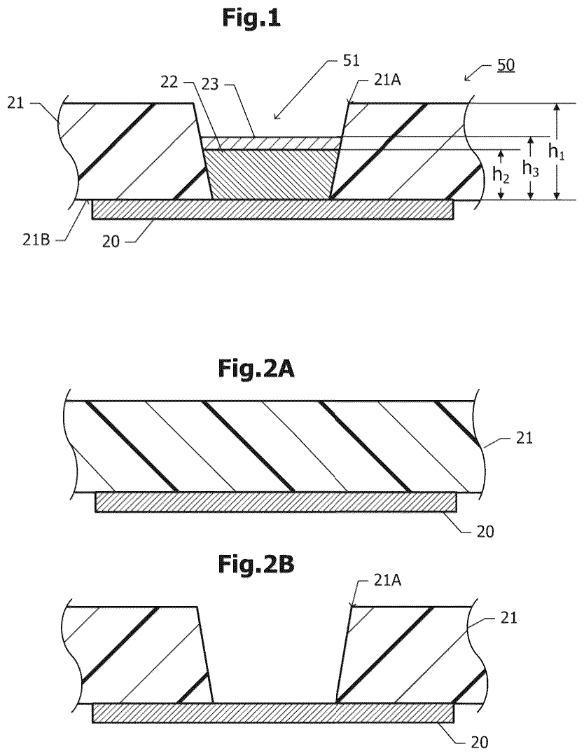

A wiring board according to a first example is described with reference to drawings of FIGS. 1 to 2B.

FIG. 1 is a sectional view of a wiring board 50 according to the first example. The wiring board 50 according to the first example includes a first insulating layer 21 in which a through-hole 21A is formed, a first conductor pattern 20, a first connection conductor 22 disposed in the through-hole 21A, and a surface treatment layer 23 disposed on a surface of the first connection conductor 22. For example, a plurality of through-holes 21A are made. In FIG. 1, one through-hole 21A is represented.

The first conductor pattern 20 is disposed on a first surface 21B that is one surface of the first insulating layer 21. The first conductor pattern 20 closes the opening of the through-hole 21A on the side of the first surface 21B. Hereinafter, a surface oriented in the opposite direction to the first surface 21B in various constituent elements is referred to as upper surface. Moreover, the direction perpendicular to the first surface 21B is sometimes referred to as thickness direction.

The side surface of the through-hole 21A is inclined such that the area of the horizontal cross section of the through-hole 21A (section parallel to the first surface 21B) becomes larger as the upward distance from the first conductor pattern 20 increases. That is, the through-hole 21A has a reverse taper shape that becomes thinner toward the lower side. When the first insulating layer 21 is viewed in a plan view (hereinafter, sometimes referred to simply as “in plan view”), the through-hole 21A is included in the first conductor pattern 20.

The first connection conductor 22 disposed in the through-hole 21A is in contact with the first conductor pattern 20. The first connection conductor 22 and the first conductor pattern 20 are formed of the same metal, for example, copper.

The surface treatment layer 23 formed on the upper surface of the first connection conductor 22 contains at least one material selected from a group consisting of Ni, Au, a solder, and flux. When the first surface 21B is employed as the basis of the height, a height h₂ to the upper surface of the first connection conductor 22 and a height h₃ to the upper surface of the surface treatment layer 23 are lower than a height h₁ to the upper surface of the first insulating layer 21. In other words, a thickness h2 of the first connection conductor 22 and a total thickness h3 of the first connection conductor 22 and the surface treatment layer 23 are less than a thickness h1 of the first insulating layer. Thus, a hollow 51 appears in the upper surface of the wiring board 50. The surface treatment layer 23 is exposed at the bottom surface of this hollow 51.

Next, a manufacturing method for the wiring board 50 according to the first example is described with reference to FIGS. 2A and 2B. FIGS. 2A and 2B are sectional views of the wiring board 50 according to the first example at a stage in the middle of manufacturing.

As depicted in FIG. 2A, a multilayer structure having the first insulating layer 21 and the first conductor pattern 20 may be formed by patterning a conductor foil of a resin sheet with the conductor foil. For example, a copper foil is used as the conductor foil. A sheet containing thermoplastic polyimide (PI) as a main material is used as the resin sheet. As a material of the resin sheet, polyetheretherketone (PEEK), polyetherimide (PEI), polyphenylene sulfide (PPS), a liquid crystal polymer (LCP), or the like may be used.

As depicted in FIG. 2B, the through-hole 21A that reaches the first conductor pattern 20 is formed from the surface on the opposite side to the surface on which the first conductor pattern 20 is disposed in the first insulating layer 21. For example, a laser processing method using a carbon dioxide laser can be applied to the formation of the through-hole 21A. This laser processing is executed with a condition under which the first conductor pattern 20 is hardly damaged.

After the through-hole 21A is formed, as depicted in FIG. 1, the first connection conductor 22 is formed by executing copper plating on the first conductor pattern 20 exposed in the through-hole 21A with use of the first conductor pattern 20 as a seed. An electroless plating method or an electrolytic plating method is used for this plating. Thereafter, the resin sheet forming the first insulating layer 21 is hardened by pressurizing and heating the resin sheet.

The wiring board 50 according to the first example is used as, for example, the uppermost layer of a mounting board for mounting an electronic component having a solder bump or the like. The solder bump of the electronic component is connected to the first connection conductor 22 through the surface treatment layer 23, and thereby the electronic component is mounted on the wiring board 50. The surface treatment layer 23 has a function of protecting the surface of the first connection conductor 22 and a function of improving the mountability in mounting the electronic component.

Next, excellent effects of the first example are described.

The interface between the first connection conductor 22 and the first conductor pattern 20 is discontinuous in terms of the shape. Thus, a stress is likely to concentrate at the interface between the first connection conductor 22 and the first conductor pattern 20 due to a difference in the thermal expansion coefficient between the wiring board 50 and the electronic component. For example, if copper is used for the first conductor pattern 20 and a solder is used for the first connection conductor 22, discontinuity of the material also occurs at the interface between both components. When the stress concentrates at the interface involving the discontinuity of the material, the likelihood of the occurrence of a crack and delamination increases.

In the first example, the first conductor pattern 20 and the first connection conductor 22 are both formed of copper. Thus, discontinuity of the material does not occur at the interface between both components. This enhances the mechanical strength of the interface between the first conductor pattern 20 and the first connection conductor 22. As a result, the likelihood of the occurrence of a crack, delamination, and the like at the interface between both components decreases.

If solder paste is used for the first connection conductor 22, a phenomenon in which a metal forming the first conductor pattern 20 melts into the solder (sometimes referred to as “solder erosion”) occurs. In the first example, the solder erosion does not occur because the first connection conductor 22 and the first conductor pattern 20 are formed of the same metal.

Further, in the first example, the hollow 51 is generated in the region in which the first connection conductor 22 is disposed. After the through-hole 21A is formed, part of the through-hole 21A on the lower side is filled with the first connection conductor 22. Thus, the center positions of the through-hole 21A and the first connection conductor 22 in plan view substantially correspond with each other. In mounting of an electronic component on the wiring board 50, a solder bump of the electronic component is positioned to the hollow 51 generated at the position of the through-hole 21A. As a result, the first connection conductor 22 and the solder bump of the electronic component can be positioned with high accuracy.

To suppress the occurrence of a crack and delamination at the interface between the first conductor pattern 20 and the first connection conductor 22, the height h₂ of the first connection conductor 22 may be equal to or larger than the thickness of the first conductor pattern 20. Moreover, to make the positioning at the time of electronic component mounting easy, the height h₂ of the first connection conductor 22 may be equal to or lower than 90% of the height h₁ of the first insulating layer 21. The total height h₃ of the first connection conductor 22 and the surface treatment layer 23 may be lower than the height h₁ of the first insulating layer 21.

Next, wiring boards according to modifications of the first example are described.

Although copper is used for the first conductor pattern 20 and the first connection conductor 22 in the first example, another same metal may be used for the first conductor pattern 20 and the first connection conductor 22. For example, silver, gold, or the like may be used.

As another form, an alloy composed mainly of copper, silver, or gold may be used for the first conductor pattern 20 and the first connection conductor 22. In a case of using an alloy for the first conductor pattern 20 and the first connection conductor 22, the constituent elements of the alloy may be the same, and the ratio of the content of the constituent elements may be the same.

Further, even when not all of the constituent elements of the alloy are the same, discontinuity of the material is alleviated and sufficient mechanical strength can be ensured as long as a main constituent element is the same. To ensure sufficient mechanical strength, the metal element with the maximum content in the first conductor pattern 20 may be the same as the metal element with the maximum content in the first connection conductor 22.

Although the plating method is used for the formation of the first connection conductor 22 in the first example, the first connection conductor 22 may be formed by another method. For example, the first connection conductor 22 may be formed by disposing electrically-conductive paste in the through-hole 21A and then curing the electrically-conductive paste. When this method is used, a binder resin remains in the first connection conductor 22. In this case, the same metal for electrically-conductive particles contained in the first connection conductor 22 and the first conductor pattern 20 may be the same.

When the plating method is employed, compared with the case of using the electrically-conductive paste, a lower portion of the through-hole 21A can be filled with the first connection conductor 22 with favorable reproducibility even when the size of the through-hole 21A in plan view is set small. Whether to employ the plating method or use the electrically-conductive paste may be determined on the basis of the size of the through-hole 21A, or the like. Moreover, when the plating method is employed, the first connection conductor 22 that does not contain the binder resin and the like and is made of a metal can be formed. In the case of using the wiring board 50 as the uppermost layer of a mounting board, the thickness of the first insulating layer 21 is at most approximately 40 μm. Thus, even when the plating method is employed, this does not cause large cost increase compared with the method of using the electrically-conductive paste.

### Second Example

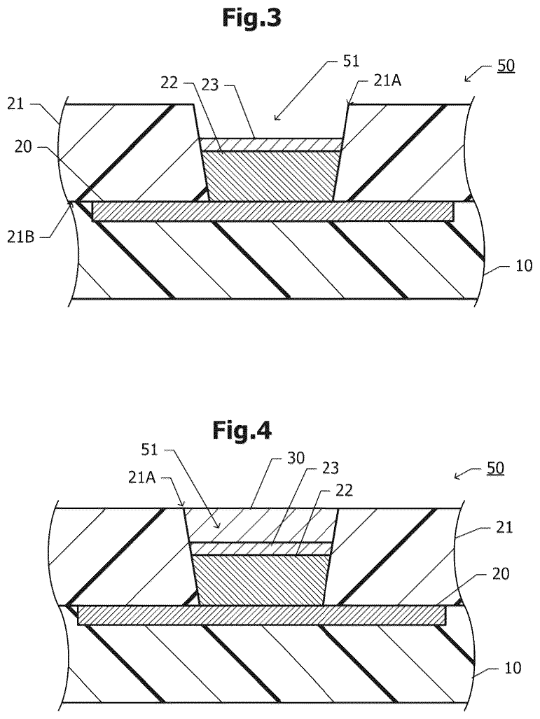

Next, a wiring board according to a second example is described with reference to FIGS. 3 and 4. In the following, description is omitted concerning a configuration common to the wiring board 50 according to the first example described with reference to FIGS. 1, 2A, and 2B.

FIG. 3 is a sectional view of the wiring board 50 according to the second example. The wiring board 50 according to the second example includes an underlying substrate 10, the first conductor pattern 20, the first insulating layer 21, the first connection conductor 22, and the surface treatment layer 23. A configuration of the first conductor pattern 20, the first insulating layer 21, the first connection conductor 22, and the surface treatment layer 23 is the same as a configuration in the wiring board 50 according to the first example (FIG. 1). The first insulating layer 21 is disposed on the upper surface of the underlying substrate 10 in such an orientation that the first surface 21B of the first insulating layer 21 is made opposite to the underlying substrate 10. The first conductor pattern 20 is disposed between the underlying substrate 10 and the first insulating layer 21. The wiring board 50 according to the second example is used as, for example, a mounting board for mounting an electronic component having a solder bump or the like.

Next, a manufacturing method for the wiring board 50 according to the second example is described. In a state in which the first surface 21B of the first insulating layer 21 that has the first conductor pattern 20 and the first connection conductor 22 and has not been subjected to heat treatment is made opposite to the upper surface of the underlying substrate 10 such as a resin sheet, the first insulating layer 21 is applied to the underlying substrate 10. In the state in which the first insulating layer 21 is applied to the underlying substrate 10, the multilayer body including the underlying substrate 10, the first conductor pattern 20, and the first insulating layer 21 is heated and pressurized to be made into a monolithic multilayer body. The surface treatment layer 23 may be formed after this heating treatment.

Next, an excellent effect of the second example is described.

Also in the second example, similarly to the first example, the mechanical strength of the interface between the first conductor pattern 20 and the first connection conductor 22 is enhanced, and the likelihood of the occurrence of a crack, delamination, and the like at the interface between both components decreases. In mounting of an electronic component on the wiring board 50, a solder bump of the electronic component is positioned to the hollow 51 generated at the position of the through-hole 21A. As a result, the first connection conductor 22 and the solder bump of the electronic component can be positioned with high accuracy.

Next, another excellent effect of the second example is described with reference to FIG. 4.

FIG. 4 is a sectional view of the wiring board 50 for explaining the other excellent effect of the second example. In mounting an electronic component on the wiring board 50, the inside of the hollow 51 formed in a surface of the wiring board 50 is sometimes filled with solder paste 30. In the second example, the side surface of the through-hole 21A is inclined such that the area of the horizontal cross section of the through-hole 21A becomes larger as the upward distance from the first conductor pattern 20 increases. This provides an excellent effect that an air void is less likely to occur when the inside of the hollow 51 is filled with the solder paste 30.

### Third Example

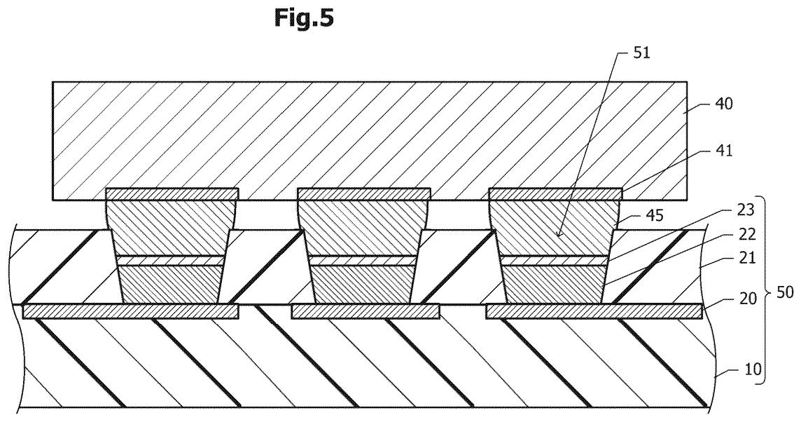

Next, an electronic module according to a third example is described with reference to FIG. 5. The electronic module according to the third example includes the wiring board 50 according to the second example (FIG. 3) and an electronic component mounted on this wiring board 50.

FIG. 5 is a sectional view of the electronic module according to the third example. A plurality of first connection conductors 22 and a plurality of surface treatment layers 23 are made in the wiring board 50. Each of a plurality of terminals 41 of an electronic component 40 is connected to the first conductor pattern 20 through a solder bump 45, the surface treatment layer 23, and the first connection conductor 22. Parts of the plurality of solder bumps 45 on the side of the wiring board 50 each exist in the hollow 51 formed in a surface of the wiring board 50.

Next, excellent effects of the third example are described. Also in the third example, similarly to the second example, an excellent effect that a crack and delamination are less likely to occur at the interface between the first conductor pattern 20 and the first connection conductor 22 is obtained. Moreover, because the plurality of solder bumps 45 each exist in the hollow 51, an excellent effect that the shear strength increases is obtained.

### Fourth Example

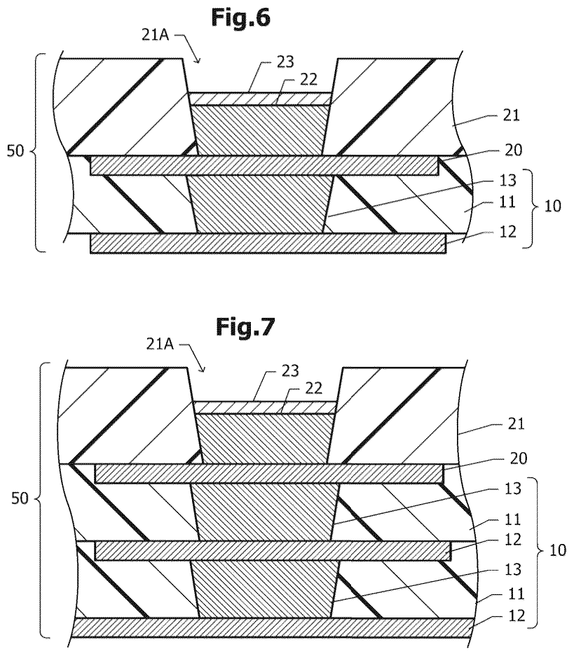

Next, a wiring board according to a fourth example is described with reference to FIG. 6. In the following, description is omitted concerning a configuration common to the wiring board 50 according to the second example described with reference to FIG. 3.

FIG. 6 is a sectional view of the wiring board 50 according to the fourth example. In the second example (FIG. 3), the detailed configuration of the underlying substrate 10 is not particularly limited. In the fourth example, the underlying substrate 10 includes a second insulating layer 11, a second conductor pattern 12, and a second connection conductor 13. The second conductor pattern 12 is disposed on the lower surface of the second insulating layer 11. In the second insulating layer 11, a via-hole that penetrates the second insulating layer 11 in the thickness direction is made. This via-hole is filled with the second connection conductor 13. The second connection conductor 13 connects the first conductor pattern 20 to the second conductor pattern 12. The second connection conductor 13 is formed of the same electrically-conductive material as the second conductor pattern 12, for example, copper. The second insulating layer 11 and the first insulating layer 21 may be formed of the same insulating material, or may be formed of different insulating materials.

Next, a manufacturing method for the wiring board 50 according to the fourth example is described.

First, the underlying substrate 10 is fabricated by a method similar to the manufacturing method for the wiring board 50 according to the first example described with reference to FIGS. 2A and 2B. In a step of filling with the second connection conductor 13, plating is executed until a surface of the second connection conductor 13 becomes substantially flush with a surface of the second insulating layer 11. Heat treatment has not yet been executed at this stage.

The first insulating layer 21 that has the first conductor pattern 20 and the first connection conductor 22 and has not been subjected to the heat treatment is applied to the underlying substrate 10 that has not been subjected to the heat treatment, and is heated and pressurized to be made into a monolithic multilayer body. The surface treatment layer 23 may be formed after the heating treatment.

Next, excellent effects of the fourth example are described.

Also in the fourth example, similarly to the second example, the occurrence of a crack and delamination at the interface between the first conductor pattern 20 and the first connection conductor 22 can be suppressed. Further, the occurrence of a crack and delamination can be suppressed also at the interface between the second conductor pattern 12 and the second connection conductor 13.

Next, modifications of the fourth example are described. Although copper is used for the second conductor pattern 12 and the second connection conductor 13 in the fourth example, another same metal may be used for the second conductor pattern 12 and the second connection conductor 13. For example, silver, gold, or the like may be used.

As another form, an alloy composed mainly of copper, silver, or gold may be used for the second conductor pattern 12 and the second connection conductor 13. In a case of using an alloy for the second conductor pattern 12 and the second connection conductor 13, the constituent elements of the alloy may be the same, and the ratio of the content of the constituent elements may be the same.

Further, even when not all of the constituent elements of the alloy are the same, discontinuity of the material is alleviated and sufficient mechanical strength can be ensured as long as a main constituent element is the same. To ensure sufficient mechanical strength, the metal element with the maximum content in the second conductor pattern 12 may be the same as the metal element with the maximum content in the second connection conductor 13.

Next, a wiring board according to a modification of the fourth example is described with reference to FIG. 7.

FIG. 7 is a sectional view of the wiring board 50 according to the modification of the fourth example. In the fourth example (FIG. 6), the underlying substrate 10 has a wiring structure of a single layer. In the modification depicted in FIG. 7, the underlying substrate 10 has a multilayer wiring structure. Each layer of the multilayer wiring structure includes the second insulating layer 11, the second conductor pattern 12, and the second connection conductor 13. The underlying substrate 10 may have the multilayer wiring structure as in the present modification.

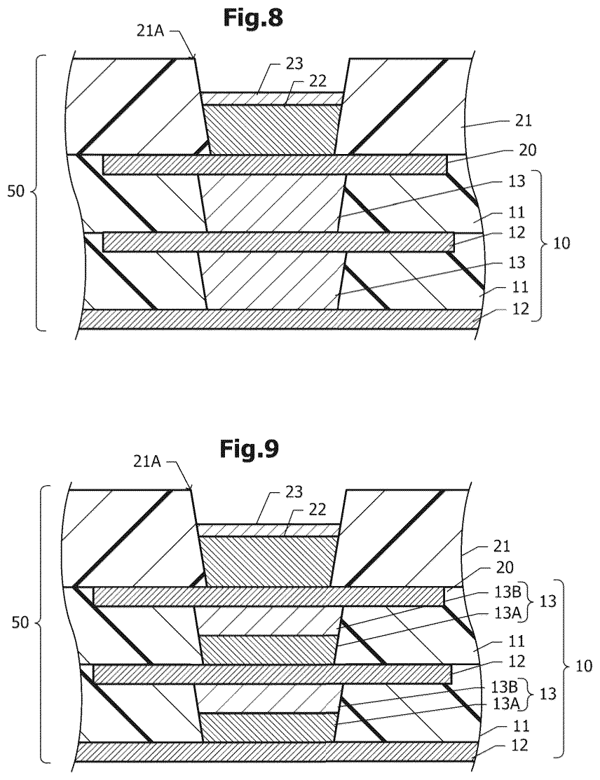

Next, a wiring board according to another modification of the fourth example is described with reference to FIG. 8.

FIG. 8 is a sectional view of the wiring board 50 according to the present modification. In the modification depicted in FIG. 7, the second connection conductors 13 are formed by a plating method with the same electrically-conductive material as the second conductor patterns 12. In contrast, in the modification depicted in FIG. 8, the second connection conductors 13 are formed by curing electrically-conductive paste. As the electrically-conductive paste, copper paste, silver paste, gold paste, solder paste, or the like can be used.

When the electrically-conductive paste is used for the second connection conductors 13 as in the present modification, the electrical connection at the interface between the second connection conductor 13 and the second conductor pattern 12 bonded onto it by pressurization and heating can be improved compared with the case of forming the second connection conductors 13 by the plating method as in the fourth example.

Next, a wiring board according to further modification of the fourth example is described with reference to FIG. 9.

FIG. 9 is a sectional view of the wiring board 50 according to the present modification. In the present modification, the second connection conductors 13 are composed of a first portion 13A on the side remoter from the first insulating layer 21 (lower side) and a second portion 13B on the side closer to the first insulating layer 21 (upper side). The first portions 13A are formed of the same electrically-conductive material as the second conductor patterns 12 similarly to the modification of the fourth example depicted in FIG. 7. The second portions 13B are formed of an electrically-conductive material obtained by curing electrically-conductive paste similarly to the modification depicted in FIG. 8.

In the present modification, the electrical connection between the first portion 13A on the lower side in the second connection conductor 13 and the second conductor pattern 12 and the electrical connection between the second portion 13B on the upper side in the second connection conductor 13 and the second conductor pattern 12 may be improved. The amount of use of the electrically-conductive paste is small compared with the modification depicted in FIG. 8. Thus, the amount of gas generated at the time of curing of the electrically-conductive paste is reduced. Moreover, the depth of the hollow to be filled with the electrically-conductive paste becomes shallow compared with the modification depicted in FIG. 8. Thus, reduction in the diameter and the pitch of the second connection conductor 13 may be realized.

### Fifth Example

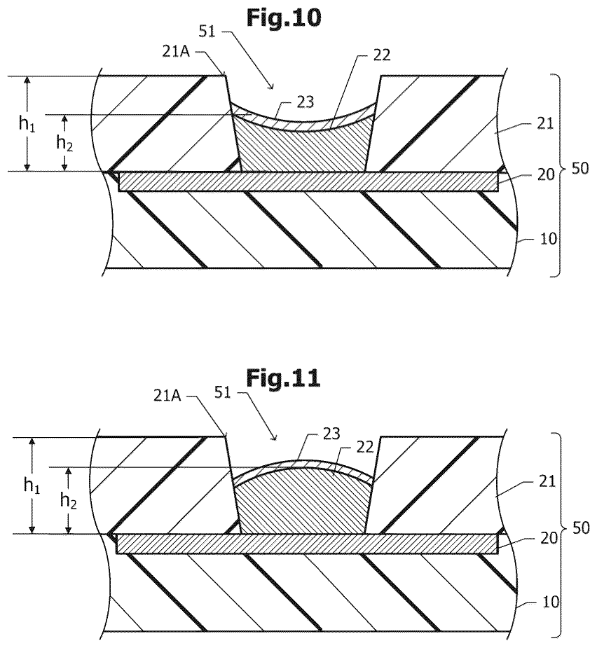

Next, a wiring board according to a fifth example is described with reference to FIG. 10. In the following, description is omitted concerning a configuration common to the wiring board 50 according to the second example described with reference to FIG. 3.

FIG. 10 is a sectional view of the wiring board 50 according to the fifth example. In the second example (FIG. 3), the upper surface of the first connection conductor 22 is substantially flat. In contrast, in the fifth example, the upper surface of the first connection conductor 22 has a concave shape curved downward. That is, a central portion of the upper surface is lower than a peripheral portion thereof. When the upper surface of the first conductor pattern 20 is employed as the basis of the height, the height h₂ to the highest position in the upper surface of the first connection conductor 22 is lower than the height h₁ to the upper surface of the first insulating layer 21. Such a shape of the upper surface of the first connection conductor 22 is obtained by adjusting a condition of plating. The surface treatment layer 23 covers the curved upper surface of the first connection conductor 22 with a substantially even thickness.

Next, excellent effects of the fifth example are described.

Also in the fifth example, similarly to the second example (FIG. 3), an excellent effect that a crack and delamination are less likely to occur at the interface between the first conductor pattern 20 and the first connection conductor 22 is obtained. Further, in the fifth example, in mounting an electronic component with a solder ball on the wiring board 50, the solder ball that the electronic component has is positioned to the lowest position in the upper surface of the first connection conductor 22. Thus, an excellent effect that the position of the electronic component is stable and the position accuracy at the time of the mounting improves is obtained.

Next, a wiring board according to a modification of the fifth example is described with reference to FIG. 11.

FIG. 11 is a sectional view of the wiring board 50 according to the modification of the fifth example. In the fifth example (FIG. 10), the upper surface of the first connection conductor 22 curves downward. In the modification depicted in FIG. 11, the upper surface of the first connection conductor 22 has a convex shape curved upward. That is, when the upper surface of the first conductor pattern 20 is employed as the basis of the height, the height of a central portion of the first connection conductor 22 is higher than that of a peripheral portion thereof. When the upper surface of the first conductor pattern 20 is employed as the basis of the height, the height h₂ to the highest position in the upper surface of the first connection conductor 22 is lower than the height h₁ to the upper surface of the first insulating layer 21. Such a shape can be implemented by adjustment of a plating condition, surface treatment, or the like.

In the present modification, in mounting an electronic component with a solder ball on the wiring board 50, the solder ball that the electronic component has comes into point contact with the highest position in the first connection conductor 22 or the surface treatment layer 23. Thus, an excellent effect that the connection between the solder ball and the first connection conductor 22 improves is obtained.

It is obvious that the above-described respective examples have been given as examples and partial replacement or combination of configurations shown in different examples is possible. Concerning similar operation and effect by a similar configuration in a plurality of examples, mention is not made for every example. Moreover, the present invention is not limited to the above-described examples. For example, it will be obvious to those skilled in the art that various changes, improvements, combinations, and the like are possible.

### REFERENCE SIGNS LIST

10 underlying substrate
11 second insulating layer
12 second conductor pattern
13 second connection conductor
13A first portion of the second connection conductor
13B second portion of the second connection conductor
20 first conductor pattern
21 first insulating layer
21A through-hole
21B first surface
22 first connection conductor
23 surface treatment layer
30 solder paste
40 electronic component
41 terminal
45 solder bump
50 wiring board
51 hollow

1. A wiring board comprising:
a first insulating layer having a through-hole that penetrates the first insulating layer in a thickness direction;
a first conductor pattern on a first surface and closes an opening of the through-hole on a side of the first surface, the first surface being one surface of the first insulating layer; and
a first connection conductor in the through-hole and connected to the first conductor pattern, a dimension of the first connection conductor in the thickness direction being smaller than a dimension of the first insulating layer in the thickness direction, wherein
a metal element with maximum content in the first conductor pattern is same as a metal element with maximum content in the first connection conductor.

2. The wiring board according to claim 1, further comprising:
an underlying substrate, wherein
the first insulating layer is on the underlying substrate, such that the first surface faces the underlying substrate, and the first conductor pattern is between the first insulating layer and the underlying substrate.

3. The wiring board according to claim 2, wherein
the underlying substrate includes a plurality of second conductor patterns, a plurality of second insulating layers, and a plurality of second connection conductors, and
the first insulating layer is on a surface of the uppermost second insulating layer among the plurality of second insulating layers.

4. The wiring board according to claim 3, wherein
a metal element with maximum content in each of the plurality of second conductor patterns is same as a metal element with maximum content in each of the plurality of second connection conductors.

5. The wiring board according to claim 3, wherein
each of the plurality of second connection conductors is an electrically-conductive material, and
each of the plurality of second conductor patterns is a different electrically-conductive material from the plurality of second connection conductors.

6. The wiring board according to claim 3, wherein
each of the plurality of second connection conductors includes a first portion in contact with a first pattern of the second conductor patterns and a second portion in contact with a second pattern of the second conductor patterns, the second pattern being closer to the first insulating layer than the first pattern, and a metal element with maximum content in the first portion is same as a metal element with maximum content in the second conductor pattern with which the first portion is in contact, and the second portion is an electrically-conductive material.

7. The wiring board according to claim 1, wherein
an upper surface of the first connection conductor has a concave shape in which a center is lower than a peripheral portion.

8. The wiring board according to claim 1, wherein
an upper surface of the first connection conductor has a convex shape in which a center is higher than a peripheral portion.

9. The wiring board according to claim 1, wherein
the through-hole has a shape widened in a direction away from the first conductor pattern.

10. The wiring board according to claim 1, wherein
the first connection conductor and the first conductor pattern are copper, silver, gold, an alloy composed mainly of copper, an alloy composed mainly of silver, or an alloy composed mainly of gold.

11. The wiring board according to claim 1, further comprising:
a surface treatment layer containing at least one material selected from a group consisting of Ni, Au, a solder, and flux on a surface of the first connection conductor.

12. The wiring board according to claim 1, wherein the first connection conductor is plated directly onto the first conductor pattern to form a monolithic metallurgical bond at an interface therebetween.

13. The wiring board according to claim 1, wherein a thickness of the first connection conductor is greater than or equal to a thickness of the first conductor pattern.

14. The wiring board according to claim 1, wherein a thickness of the first connection conductor is no more than 90% of a thickness of the first insulating layer.

15. The wiring board according to claim 1, wherein the first insulating layer comprises a material selected from the group consisting of thermoplastic polyimide (PI), polyetheretherketone (PEEK), polyetherimide (PEI), polyphenylene sulfide (PPS), and a liquid crystal polymer (LCP).

16. An electronic module comprising:
the wiring board according to claim 1; and
an electronic component mounted on the wiring board, with a solder bump interposed therebetween, wherein
the solder bump is connected to the first connection conductor.

17. The electronic module according to claim 16, wherein a portion of the solder bump is within a hollow defined by an upper portion of the through-hole above the first connection conductor.

18. A manufacturing method for a wiring board, the manufacturing method comprising:
preparing a first insulating layer having a first surface on which a first conductor pattern is formed, the first surface being one surface of the first insulating layer;
forming a through-hole that reaches the first conductor pattern from a surface on an opposite side to the first surface in the first insulating layer; and
forming a first connection conductor in the through-hole by a plating method with use of the first conductor pattern as a seed, wherein
a metal element with maximum content in the first conductor pattern is same as a metal element with maximum content in the first connection conductor, and
a dimension of the first connection conductor in a thickness direction is smaller than a dimension of the first insulating layer on the first conductor pattern in the thickness direction.

19. The manufacturing method according to claim 18, wherein forming the through-hole includes laser processing the first insulating layer to expose the first conductor pattern.
